(19) United States
(12) Patent Application Publication
(10) Pub. No.: US 2026/0262280 A1
(43) Pub. Date: Sep. 3, 2026

(54) IMPROVED POLYSILICON RESISTORS USING IMPLANTED CHLORINE WITHIN AN INTEGRATED CIRCUIT

(71) Applicant: Texas Instruments Incorporated, Dallas, TX (US)

(72) Inventors: Mark F. Arendt, Richardson, TX (US); Damien Gilmore, Allen, TX (US)

(21) Appl. No.: 19/066,664

(22) Filed: Feb. 28, 2025

(51) Int. Cl. H10D 84/40; H10D 62/50; H10D 84/01

(52) U.S. Cl. CPC H10D 84/403; H10D 62/50; H10D 84/0109; H10D 84/013; H10D 84/0144

(57) ABSTRACT

A method of forming an integrated circuit comprises: (i) forming plural semiconductor bodies, over a semiconductor substrate, wherein a first semiconductor body in the plural semiconductor bodies corresponds to a resistor and a second semiconductor body in the plural semiconductor bodies corresponds to a transistor; (ii) forming a mask over the semiconductor substrate, the mask including a first open area providing an unmasked portion of the first semiconductor body and a second open area providing an unmasked portion in or adjacent to the second semiconductor body; and (iii) implanting at least one of an n-type or p-type dopant, and chlorine, through the first open area into the first semiconductor body and through the second open area into a region in or adjacent the second semiconductor body.

### CROSS-REFERENCE TO RELATED APPLICATION

Not applicable.

### BACKGROUND

Integrated circuits (IC or ICs) may include various types of circuit devices, including as examples transistors (bipolar and field effect), diodes, and resistors. IC semiconductor fabrication involves a sequence of steps, where often attributes of a step apply simultaneously to a structure of more than one of these circuit devices. Accordingly, an adjustment to a fabrication step that may be addressed to one of the circuit device types also must be considered in terms of what impact it may have on a different and concurrently formed circuit device (or part of that device). Examples are provided below in view of such considerations, which also may improve on at least one of resistor formation and performance.

### SUMMARY

In an example, there is a method of forming an integrated circuit. The method comprises: (i) forming plural semiconductor bodies, over a semiconductor substrate, wherein a first semiconductor body in the plural semiconductor bodies corresponds to a resistor and a second semiconductor body in the plural semiconductor bodies corresponds to a transistor; (ii) forming a mask over the semiconductor substrate, the mask including a first open area providing an unmasked portion of the first semiconductor body and a second open area providing an unmasked portion in or adjacent to the second semiconductor body; and (iii) implanting at least one of an n-type or p-type dopant, and chlorine, through the first open area into the first semiconductor body and through the second open area into a region in or adjacent the second semiconductor body.

Other aspects are also described and claimed.

### BRIEF DESCRIPTION OF THE DRAWINGS

FIG. 1 is a plan and partial view of a semiconductor device, as part of an example including three different resistance resistors, a diode, a bipolar junction transistor (BJT), a p-type metal oxide semiconductor (PMOS) transistor, and an n-type metal oxide semiconductor (NMOS) transistor.

FIGS. 2 through 11 are cross-section views representing successive fabrication stages and resultant structures of the FIG. 1 semiconductor device.

FIG. 12 is a flow diagram of an example method of various steps for forming the FIG. 1 semiconductor device.

### DETAILED DESCRIPTION

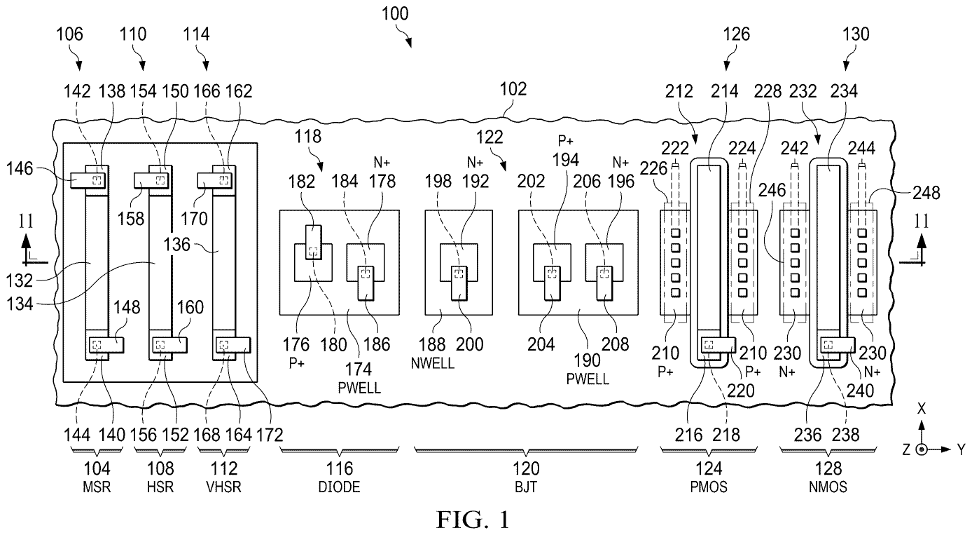

Examples are described with reference to the attached figures, which may not be drawn to scale. Several aspects are described with reference to example applications for illustration, in which like features correspond to like reference numbers. In FIG. 1 and various later figures, two or more dimensions are shown and indicated in an x-y-z coordinate space, where in FIG. 1 a plan view is shown in the x-y plane but should be understood to also have features in the z-dimension, understood to be extending in a direction out of the plane of the image. The directional references are for purposes of relative placement, but such terms are not intended to be restrictive as the device may be rotated in space and thereby change absolute, but not relative, references. Numerous specific details, relationships, and methods are set forth to provide an understanding, but the scope is not necessarily limited by the illustrated ordering of acts or events, as some acts may occur in different orders and/or concurrently with other acts or events. Further, not all illustrated acts or events may be required to implement a methodology in accordance with one or more examples.

The examples relate to semiconductor IC fabrication, and more particularly but not exclusively to an IC that includes one or more semiconductor (e.g., polycrystalline silicon, also known as polysilicon) resistors, along with other devices. IC fabrication of plural devices in connection with a same semiconductor substrate, such as resistors and any one or more of transistors and diodes, typically involves multiple steps. In such fabrication, sometimes it is undesirable to include one or more steps that are limited to only one or the other device, which may thereby increase the total number of required fabrication steps. Such an approach can be particularly undesirable in low-cost device/process flows. For example, in a low-cost flow, there may be a preference not to use a separate mask, and its related steps of patterning, implanting, and mask removal, for purposes of having to implant dopants only into resistors (or resistors and other devices), so as to achieve a desired resistance value in the implanted resistors. As another example, when a step is taken as to some devices, impacts are evaluated so as not to permit an unacceptable impact on other devices. For example, a so-called affinity matrix may indicate or dictate the relationship between different types of IC devices and guide that a process step or steps used with respect to one or more device types cannot impact one or more other devices, beyond an acceptable degree. The examples herein consider such aspects, in improving resistor methodology and apparatus, with a goal that an impact on other devices, if any, is within an acceptable tolerance. Further, while the preceding may apply to various baseline devices, this document provides examples that may improve on certain of the above concepts, as detailed below. While such examples may be expected to provide various advantages as described above, no particular result is a requirement unless explicitly recited in a particular claim.

FIG. 1 is a plan and partial view of a semiconductor device 100, e.g. a portion of an IC. The semiconductor device 100 includes a semiconductor substrate 102, for example as part of a silicon wafer. Such a wafer typically includes multiple locations, each corresponding to a same or different IC on the wafer, so the illustration of FIG. 1 (and later figures) can be repeated in each wafer IC location. The wafer typically provides either a p-type or n-type semiconductor, and the semiconductor substrate 102 can represent a portion of the bulk wafer or a region (e.g., a well and/or buried layer and/or epitaxial layer) formed in connection with the wafer. As detailed in the remaining figures, numerous device areas are provided, into which are ultimately formed examples of respective devices; these areas, and corresponding devices, include: (i) a medium sheet resistor (MSR) area 104 for an MSR 106; (ii) a high sheet resistor (HSR) 108 area for an HSR 110; (iii) a very high sheet resistor (VHSR) area 112 for a VHSR 114. “sheet” being an abbreviation of “sheet resistance. The resistors 106, 108, and 110 are representative of resistors having one of various configurations, including linear as shown, and serpentine, not shown. Also shown are various devices other than resistors, including (iv) a diode area 116 for a diode 118; (v) a BJT area 120 for a BJT 122; (vi) a PMOS area 124 for a PMOS transistor 126; and (vii) an NMOS area 128 for an NMOS transistor 130. Each of the devices is represented by certain general features and corresponding areas in FIG. 1, with additional details, options, and attributes described later. Ultimately, the figures and corresponding descriptions provide resistor, diode, and transistor examples that may provide one or more benefits, as described below.

All of the MSR 106, HSR 110, and VHSR 114 have comparable geometric features, with differences in respective resistance or resistivity values, and dopant implants achieving those values, as detailed later. Turning first to geometries, each of the MSR 106, HSR 110, and VHSR 114 includes a respective semiconductor body 132, 134, and 136 (e.g., of polysilicon or polysilicon germanium), positioned over the semiconductor substrate 102. Each semiconductor body 132, 134, and 136 has a major axis in the x-dimension, along which the respective semiconductor body 132, 134, and 136 may have a length, for example, in a range from 0.2 μm to 100 μm and a width (in the y-dimension) in a range from 0.03 μm to 50 μm. The semiconductor body 132 includes opposing metalized ends 138 and 140, each coupled by a respective contact 142 and 144 to a respective one of metal layer structures 146 and 148. The semiconductor body 134 includes opposing metalized ends 150 and 152, each coupled by a respective contact 154 and 156 to a respective metal layer structure 158 and 160. The semiconductor body 136 includes opposing metalized ends 162 and 164, each coupled by a respective contact 166 and 168 to a respective metal layer structure 170 and 172. As to resistance values, generally each of the MSR 106, HSR 110, and VHSR 114 has a respective sheet resistance within a corresponding range, for example with the sheet resistance of the MSR 106 being between 50 Ω/square and 190 Ω/square, the sheet resistance of the HSR 110 being between 250 Ω/square and 360 Ω/square, and the sheet resistance of the VHSR 114 being between 1.0 kΩ/square and 3.0 kΩ/square.

The diode 118 includes a first PWELL 174, which is a region of p-type semiconductor material formed within the semiconductor substrate 102. The diode 118 further includes a p-type anode 176 and an n-type cathode 178, each formed adjacent one another and in the first PWELL 174. For purposes of this structure and document (including other structures described), the term adjacent is intended to define two (or more) items that are sufficiently nearby one another so as to implement or provide an intended device structure and functionality. For example, each of the p-type anode 176 and the n-type cathode 178 may be formed into the semiconductor substrate 102 by dopant implants, respectively, of a relatively high p-type (shown as P+) and a relatively high n-type (shown as N+), whereby the anode and cathode regions 176 and 178 are sufficiently close to one another to provide the known structure and function of a diode. Specifically, the adjacency of the p-type anode 176 and the n-type cathode 178 provides a PN structure that may be forward biased at the diode junction so as to conduct current across the junction (or, for certain diodes, to desirably reverse breakdown). The diode junction forms a depletion region between the p-type anode 176 and the n-type cathode 178. The diode 118 also includes electrical connectivity structures, in which the p-type anode 176 has a contact 180 to a metal layer structure 182, and the n-type cathode 178 has a contact 184 to a metal layer structure 186.

The BJT 122 is shown by example as an NPN BJT, with the understanding that the semiconductor device 100 could alternatively or additionally include a PNP BJT. The BJT 122 includes a first NWELL 188, which is a region of n-type semiconductor material formed within the semiconductor substrate 102, and the BJT 122 also includes a second PWELL 190. The BJT 122 further includes an n-type collector 192 in the NWELL 188, and a p-type base 194 and an n-type emitter 196 both in the second PWELL 190. The BJT 122 also includes electrical connectivity structures, including: (i) a contact 198 to the n-type collector 192 and a metal layer structure 200 to the contact 198; (ii) a contact 202 to the p-type base 194 and a metal layer structure 204 to the contact 202; and (iii) a contact 206 to the n-type emitter 196 and a metal layer structure 208 to the contact 206.

The PMOS transistor 124 includes a moat 210, shown by a dotted line to represent an intended area in which the transistor source/drain regions are formed on opposing sides of a transistor gate 212, as further described below. The moat 210 may include a well or other region that is complementary to the dopant type of the source/drain regions formed in the moat 210. Accordingly for the PMOS transistor 126, each of the source and drain regions are heavily doped p-type, and the moat 210 may include a complementary conductivity type (e.g., n-type). Other alternatives or variations are understood in the art (e.g., buried layers, epitaxial layers, wells, and the like). The transistor gate 212 includes a polysilicon transistor gate 214. In an example, the polysilicon transistor gate 214 is formed in the same polysilicon formation/masking and etch step(s) as the resistor semiconductor bodies 132, 134, and 136. As detailed later, in some examples, a same dopant implant, such as an N+ implant, may be introduced, for example concurrently, into both the gate polysilicon transistor gate 214 and the semiconductor body 132 of the MSR 106, and additionally chlorine also may be implanted in both. Accordingly, in such examples a mutual doping and/or chlorine implant step may achieve favorable device attributes in the MSR 104 without any unacceptable negative impact on the polysilicon transistor gate 214.

Various regions of the PMOS transistor 126 are accessible by various conductive structures. For example, a gate silicide 216 is formed at one end of the polysilicon transistor gate 214. A metal contact 218 is connected to the gate silicide 216 and to a metal layer structure 220. Further, source/drain silicides may be formed within the perimeter of the moat 210, for example at the same time as the gate silicide 216, but are not visible in FIG. 1 as they are below other illustrated structures. Thereafter, and by example at the same time the metal contact 218 is formed, a first conductor set 222, including one or more conductive contacts, is formed on a first side of the polysilicon transistor gate 214 and downward in the z-dimension to a first source/drain silicide, again not visible in FIG. 1. And, a second conductor set 224, including one or more conductive contacts, is formed on a second side, opposite the first side, of the gate conductor polysilicon transistor gate 214 and downward in the z-dimension to a second source/drain silicide, again not visible in FIG. 1. Accordingly, the first conductor set 222 may electrically communicate with a first source/drain region in the moat 210, and the second conductor set 224 may electrically communicate with a second source/drain region in the moat 210. Lastly, the first conductor set 222 conducts to, and also may be part of, a metal layer structure 226, and the second conductor set 224 conducts to, and also may be part of, a metal layer structure 228.

The NMOS transistor 130 includes structures comparable to and generally formed at the same time as the PMOS transistor 126, with the exception of the complementary materials for the source/drain regions. Accordingly, the NMOS transistor 130 includes a p-type moat 230, in which the transistor heavily doped (N+) n-type source/drain regions are formed on opposing sides of a transistor gate 232. The transistor gate 232 includes a polysilicon transistor gate 234 which, for example, is formed in the same polysilicon formation/masking and etch step(s) as the resistor semiconductor bodies 132, 134, and 136 and the PMOS polysilicon transistor gate 214. The NMOS transistor 130 also includes various conductive structures. For example, a gate silicide 236 is formed at one end of the polysilicon transistor gate 234, to which is connected a metal contact 238 which further connects to a metal layer structure 240. Further, source/drain silicides may be formed within the perimeter of the moat 230, for example at the same time as the gate silicide 236, and which are not visible in FIG. 1 as they are below other illustrated structures. Thereafter, and by example at the same time the metal contact 238 is formed, a third conductor set 242 and a fourth conductor set 244, each including one or more conductive contacts, are formed on opposing sides of the polysilicon transistor gate 234 and downward in the z-dimension to respective source/drain silicides. Accordingly, the third conductor set 242 may electrically communicate with a first source/drain region in the moat 230, and the second conductor set 224 may electrically communicate with a second source/drain region in the moat 230. Lastly, the third conductor set 242 conducts to, and also may be part of, a metal layer structure 246, and the fourth conductor set 244 conducts to, and also may be part of, a metal layer structure 248.

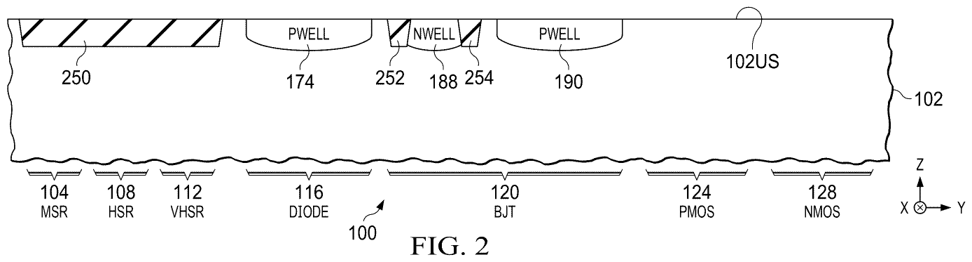

FIGS. 2 through 11 are cross-sectional views, for example in the +x-dimension (y-z plane) across FIG. 1, representing successive fabrication stages and resultant structures of the FIG. 1 semiconductor device 100. In FIG. 2, the semiconductor device 100 is provided at an early manufacturing stage. The semiconductor device 100 includes the semiconductor substrate 102, for example as part of a silicon wafer. Such a wafer typically includes multiple locations, each corresponding to a same or different IC on the wafer, so the illustration of FIG. 2 (and later figures) can be repeated in each wafer IC location. The wafer typically provides either a p-type or n-type semiconductor, and the semiconductor substrate 102 can represent a portion of the bulk wafer or a region (e.g., a well, buried layer or epitaxial layer) formed in connection with the wafer. As introduced above, and detailed in the remaining figures, the semiconductor substrate 102 includes the various device areas, namely, the MSR area 104, the HSR area 108, the VHSR area 112, the diode area 116, the BJT area 120, the PMOS area 124, and the NMOS area 128. Ultimately, these figures, and the corresponding descriptions, may provide for any one or more of an efficient, cost-sensitive formation of devices in one or more of these areas.

Also in connection with FIG. 2, the semiconductor substrate 102 includes an upper surface 102US. Isolation structures 250, 252, and 254 are formed beneath the upper surface 102US. Each of the isolation structures 250, 252, and 254 may be, for example, a shallow trench isolation (STI) structure. The isolation structure 250 corresponds to the three resistor areas 104, 108, and 112, while the surface isolation structures 252 and 254 serve to provide isolation between each of the PWELL 174, the NWELL 188, and the PWELL 190, all shown and described above in connection with FIG. 1. Each of the isolation structures 250, 252, and 254 may have an x-dimension thickness in a range of 150 nm to 600 nm. Alternative isolation methods also may be used, such as a different insulator, a local oxidation of silicon (LOCOS) structure, or a doped well region. While not shown, after forming the isolation structures 250, 252, and 254, a threshold voltage (Vt) implant may be applied to the semiconductor substrate 102, with dopant type and energy selected to ultimately adjust the Vt of the later-formed PMOS 126 and NMOS 130 transistors. Meanwhile, the isolation structure 250 essentially blocks the implant dopants in the substrate 102 from having an effect on the resistor in the resistor areas 104, 108, and 112. The isolation structure 250 also may later conductively isolate each of the resistors 106, 110, and 114 from the substrate 102.

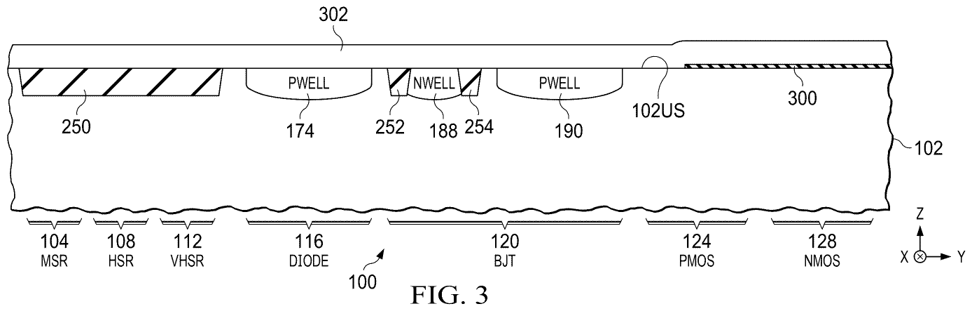

In FIG. 3, a gate oxide layer 300 is formed across a portion of the upper surface 102US, for example in the PMOS and NMOS areas 124 and 128, by oxidizing an exposed portion of the upper surface 102US. The gate oxide layer 300 may have an x-dimension thickness from 2 nm to 50 nm. Thereafter, a polysilicon layer 302 is deposited atop the entire illustrated structure, thereby conforming to the gate oxide layer 300 and an upper surface of the remaining FIG. 3 structures. The polysilicon layer 302 may be undoped when deposited, or may be in-situ doped and/or doped by implant in some examples.

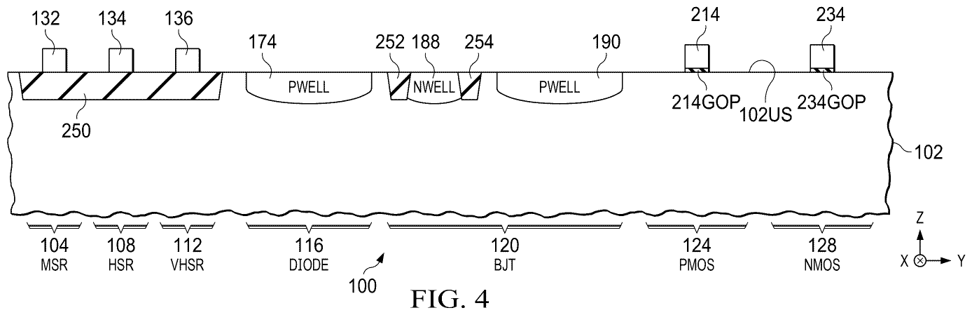

In FIG. 4, a mask (e.g., photoresist, not shown) is formed and patterned over the FIG. 3 polysilicon layer 302, and the polysilicon layer 302 is correspondingly etched so that the required structures of the polysilicon layer 302 remain, thereby providing the above-introduced semiconductor bodies 132, 134, and 136, and the polysilicon transistor gates 214 and 234. Further, the polysilicon etch is continued to the upper surfaces 102US (and upper surface of each of the surface isolation structures); to the right in FIG. 3, therefore, the etch removes exposed portions of the FIG. 3 gate oxide layer 300, while leaving the unexposed portion of the oxide layer 302 beneath each of the polysilicon transistor gates 214 and 234, where each such oxide portion is hereafter referred to as a respective gate oxide portion 214GOP and 234GOP. In some other examples, the polysilicon layer 302 may be formed over an unpatterned gate oxide layer 300, with portions of the gate oxide layer 300 over the diode 116 and BJT 120 removed during the polysilicon etch.

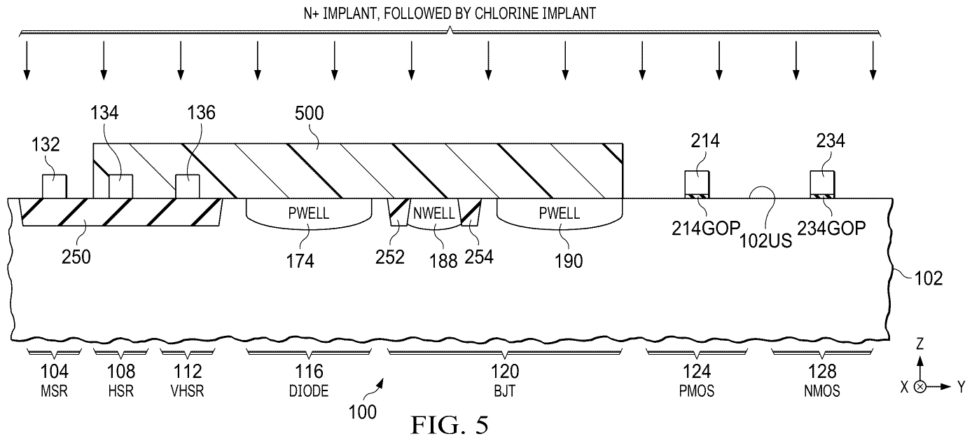

In FIG. 5, a mask 500 is formed over certain areas and structures, and two implants are performed into the unmasked areas by the mask 500, namely, the MSR area 104, the PMOS area 124, and the NMOS area 128. Specifically, a first of the FIG. 5 implants is referred to as an N⁺ implant, indicating a relatively high dose of n-type dopants, such as phosphorus, arsenic, or antimony. For example, the FIG. 5 N⁺ implant may be of phosphorus at an energy in a range of 30 keV to 50 keV, and with a dose in a range of 1e15 to 1e16 atoms/cm². A second of the FIG. 5 implants is a chlorine implant, for example at an energy in a range of 10 keV to 50 keV and with a dose in a range of 2e14 to 8e15 atoms/cm². Optionally the chlorine implant may be performed before the N⁺ implant. As to the chlorine implant, note that doses outside this range may have undesirable impacts. For example, lower-dose chlorine implants, for example of 1e14 atoms/cm² or below, may not desirably affect the resistance of the MSR 106 (or, for later steps, the HSR 110 and VHSR 114), while higher-dose chlorine implants, for example of 1e16 atoms/cm² or higher, may undesirably impact (e.g., amorphize) the crystalline structure of the implanted polysilicon.

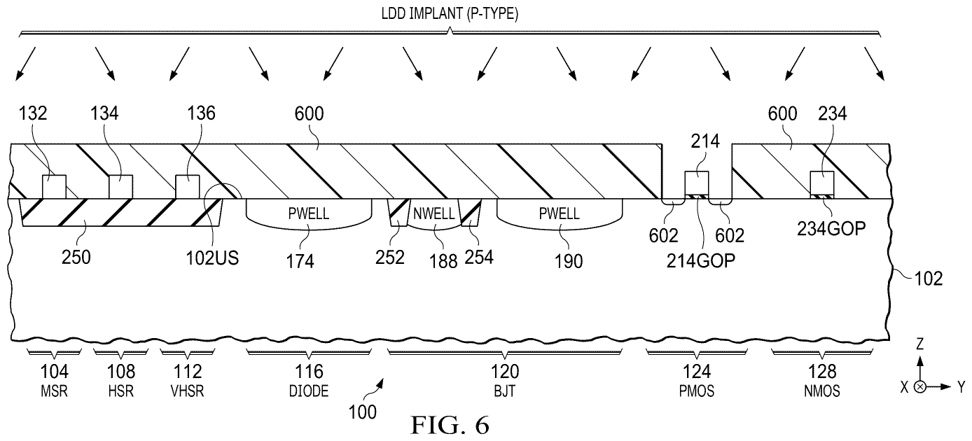

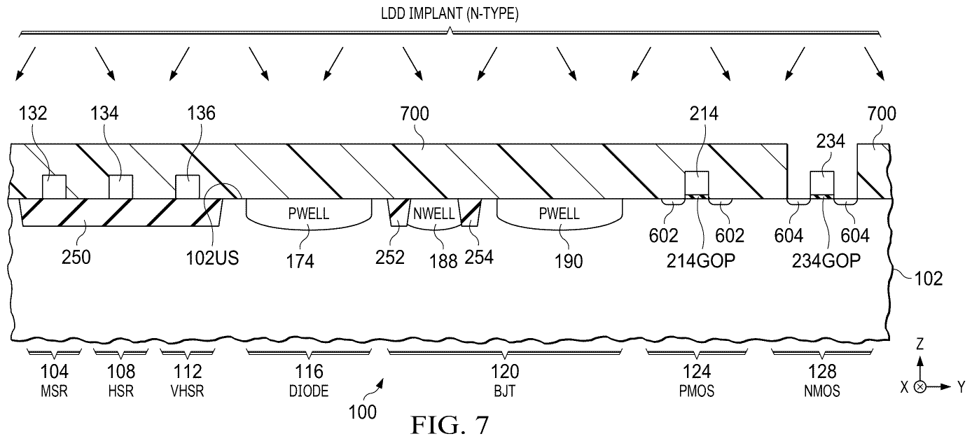

In FIGS. 6 and 7, respective masks 600 and 700 are formed over certain areas and structures, leaving unmasked in FIG. 6 the polysilicon transistor gate 214, and leaving unmasked in FIG. 7 the transistor gate 234. Also in FIGS. 6 and 7, a y-dimensional lateral space is unmasked on both sides of each of the corresponding unmasked transistor gates 214 and 234. Next, a relatively light dopant implant, commonly referred to as a lightly doped drain (LDD) implant, is performed, thereby forming corresponding LDD regions 602 below the upper surface 102US and that self-align to the gate oxide portion 214GOP for the PMOS area 124 and similarly forming corresponding LDD regions 604 below the upper surface 102US and that self-align to the gate oxide portion 234GOP for the NMOS area 128. The LDD implant is typically provided at an energy lower than either an NSD or PSD implant (as described below), and a dopant type of the LDD is selected according to the desired conductivity type of the corresponding transistor. Accordingly, in FIG. 6, a p-type LDD implant is performed for the PMOS transistor 126 being formed in the PMOS area 124, and in FIG. 7, an n-type LDD implant is performed for the NMOS transistor 130 being formed in the NMOS area 128.

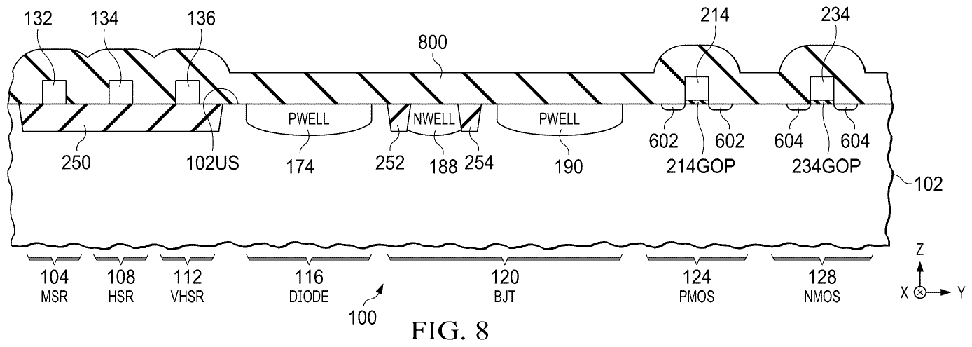

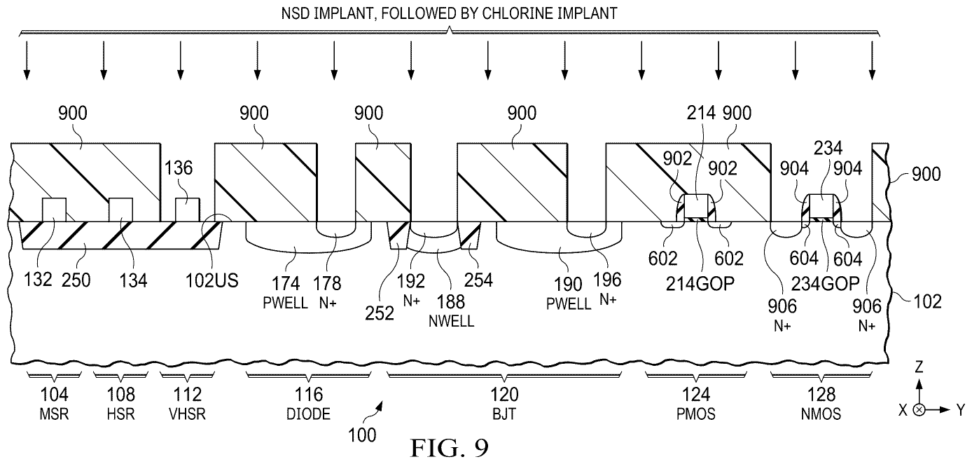

In FIG. 8, a layer 800 (or multiple separate layers) is formed over the FIG. 7 structure, in preparation to form alignment spacers in a later manufacturing stage. In the illustrated example, there is a single layer 800, but other examples are contemplated. The layer 800 may be formed from a dielectric material, such as oxide or nitride, or again from multiple layers, selected for example from oxide or nitride. The layer 800 may have a total x-dimension thickness from 10 nm to 120 nm, by ways of example. After the layer 800 is formed, it is blanket etched down to the upper surface 102US (and surfaces of the isolation structures 250, 252, and 254), thereby forming a respective spacer 902 for the polysilicon transistor gate 214 and a spacer 904 for the polysilicon transistor gate 234, as further shown in FIG. 9.

In FIG. 9, a mask 900 is formed over certain areas and structures, and two implants are performed into the areas not covered (unmasked) by the mask 900, namely, the VHSR area 112, a first portion of the diode area 116, first and second portions of the BJT area 120, and a portion of the NMOS area 128. A first implant is an n-type dopant implant is performed into the unmasked areas. The FIG. 9 n-type implant may be referred to as a n-type source/drain (or NSD) implant as the implant forms, among other things, n-type source/drain regions 906 for at least the NMOS transistor 130 being formed in the NMOS area 128. Concurrently, any other unmasked area receives the NSD implant, thereby including implanted n-type dopants into the semiconductor body 136 in the VHSR area 112, the first portion of the first PWELL 174 in the diode area 116 and thereby forming the n-type cathode 178, the NWELL 188 and thereby forming the n-type collector 192, and the first portion of the second PWELL 190 and thereby forming the n-type emitter 196. The FIG. 9 n-type implant again may include n-type dopants such as phosphorus, arsenic, or antimony, with an example using phosphorus at an energy range of 25 keV to 60 keV, and with a dose in a range of 0.8e15 to 5e15 atoms/cm². A second of the FIG. 9 implants is a chlorine implant, for example at an energy range of 10 keV to 50 keV and dose in a range of 2e14 to 8e15 atoms/cm².

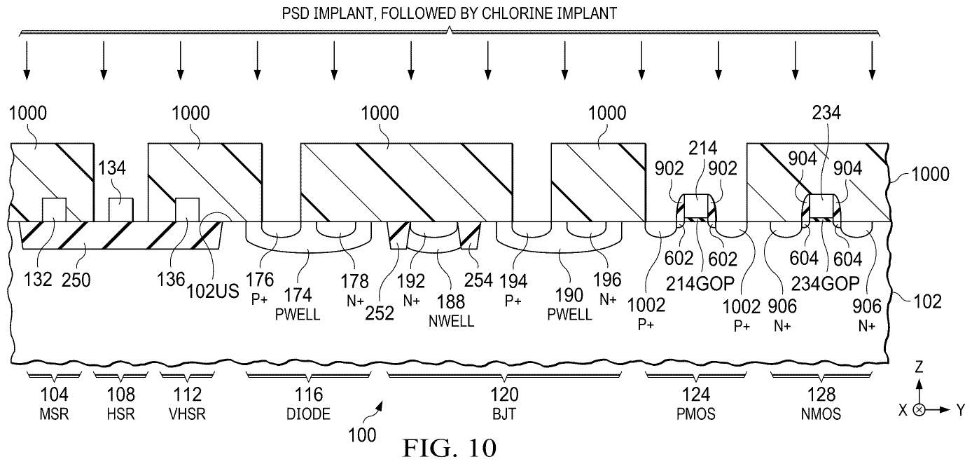

In FIG. 10, a mask 1000 is formed over certain areas and structures, and two implants are performed into the areas not covered (unmasked) by the mask 1000, namely, the HSR area 108, a second portion of the diode area 116, a second portion of the PWELL 190 in the BJT area 120, and a portion of the PMOS area 124. A first implant is a p-type dopant implant into the unmasked areas. The FIG. 10 p-type implant may be referred to as a p-type source/drain (or PSD) implant, as the implant forms, among other things, p-type source/drain regions 1002 for at least the PMOS transistor 126 being formed in the PMOS area 124. Concurrently, any other unmasked area receives the PSD implant, thereby including implanted p-type dopants (e.g., BF₂, boron, and/or indium or germanium PAI) into the semiconductor body 134 in the HSR area 108, the second portion of the first PWELL 174 in the diode area 116 and thereby forming the p-type anode 176, and the second portion of the PWELL 190 and thereby forming the p-type base 194. An example of the FIG. 10 p-type implant uses boron at an energy in a range of 5 keV to 18 keV, and with a dose in a range of 0.8e15 to 4e15 atoms/cm². A second of the FIG. 10 implants is a chlorine implant, for example at an energy in a range of 10 keV to 50 keV and in a dose in a range of 2e14 to 8e15 atoms/cm².

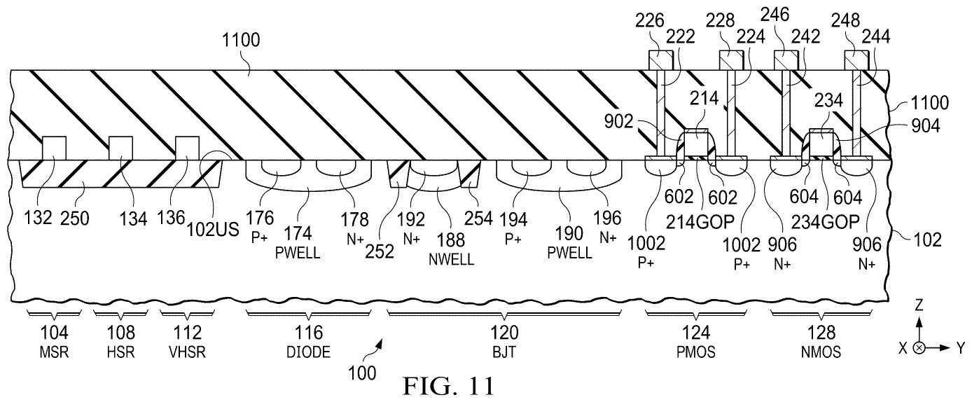

In FIG. 11, a dielectric layer 1100 is formed over the structure. Thereafter metal connectivity structures introduced from FIG. 1 are formed, and those along the indicated FIG. 1 cross-sectional line are shown in FIG. 11. These structures include the first, second, third, and fourth conductor sets 222, 224, 242, and 244 through the dielectric layer 1100, and the respective metal layer structures 226, 228, 246, and 248 connected thereto.

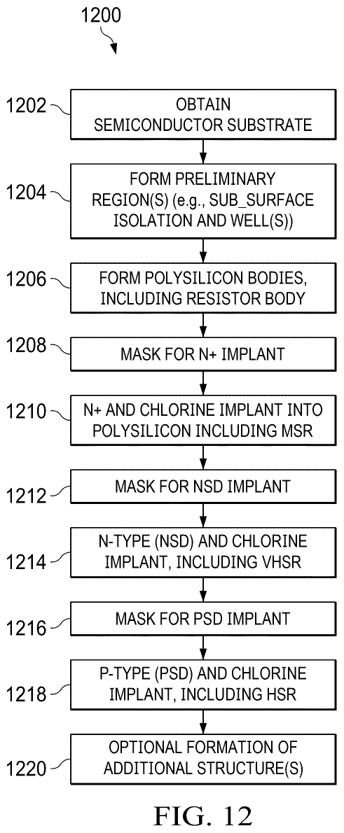

FIG. 12 is a flow diagram of an example method 1200 of various steps summarizing various of the above-described steps for manufacturing the semiconductor device 100 (e.g. an IC), for example as depicted in FIGS. 1-11. The method 1200 begins in a step 1202, in which the FIG. 1 semiconductor substrate 110 is obtained. The semiconductor substrate 102 at this stage may be a bare wafer or may have or one or more semiconductor features already formed on it. Next, in a step 1204, one or more preliminary structures are formed, such as surface isolation, buried layers, and wells. For example, the step 1204 may form the FIG. 2 isolation structures 250, 252, and 254 and/or the PWELLS 174 and 190 and the NWELL 188. Next, in a step 1206, polysilicon bodies are formed over one or more of the isolation structures, e.g. LOCOS or STI, the bodies corresponding to at least a resistor and some other device such as a transistor. For example, the step 1206 may form the FIG. 4 semiconductor bodies 132, 134, and 136 for multiple resistors and the polysilicon transistor gates 214 and 234 for multiple transistors. Next, in a step 1208, a mask is formed with one or more open areas that define unmasked portions of the semiconductor structure. Next, in a step 1210, implants of one or more dopants, and chorine, are performed though the step 1208 open areas. Also in an example, the dopant and chlorine implants are performed at different times (but still through the same open areas), for example first with a semiconductor dopant (e.g., N+ dopant) and then second with chlorine. Optionally the chlorine implant may be performed before the N⁺ implant. After the step 1210, the pair of steps 1212 and 1214 perform comparable actions with respect to another mask, open areas through the mask, and a different dopant or dose, namely, with respect to the NSD implant through the mask open areas and into a selected polysilicon body and/or regions adjacent a polysilicon body. For example, see FIG. 9. And thereafter, the pair of steps 1216 and 1218 perform comparable actions with respect to another mask, open areas, and a different dopant or dose, namely, with respect to the PSD implant. For example, see FIG. 10. After the step 1218, as shown generally in a step 1220, additional structures may be formed, for example including one or more additional insulating and/or connectivity and/or encapsulating structures.

From the above, one skilled in the art should appreciate that examples are provided for semiconductor IC fabrication, for example with respect to an IC that includes both polysilicon resistors and other devices, such as diodes or transistors (either BJT and/or MOS). Masking and implant steps used for such other devices also may be used, for example by a mask shared with either an n-type or p-type implant, so that a structure of a device other than a resistor and unmasked to receive either the n-type of p-type implant also receives chlorine at the same time as a resistor body, whereby the chlorine desirably adjusts the resistance of the resistor body, without unduly or negatively impacting the non-resistor device. Examples are provided of various process parameters, as may be adjusted based on the teaching of this document. Additionally, the above ranges are provided by way of examples, and the viability or results of such ranges may interact with other variables, such as technology constraints. Further, the use of chlorine as described herein may be used with resistors of differing resistance values. Accordingly, polysilicon resistors can be tuned to a desirable resistance in this manner. For example, a 1e15 atoms/cm² chlorine implant into an LSR, MSR and VHSR may respectively increase the sheet resistance by about 2%, 20% and 40%. The chlorine dose may be selected within the previously described range to result in a target value, without adversely affecting the performance of other non-resistor devices. Another benefit may be that resistor drift may be unaffected, or even reduced, by the additional chlorine implant into the resistor polysilicon body. As still another benefit, the chlorine implants as described in this document may have a same or comparable impact across multiple polysilicon morphologies, that is, polysilicon deposited using different temperatures, gas flows, pressures, etc. For example, the above describes each of MSR, HSR, and VHSR resistors. In some examples, the polysilicon for all three of these resistor-types starts out with a same thickness, while the final sheet resistance and grain size for each is a function of the constituent dopant dose and post-implant thermal cycling (e.g., MSR is more heavily doped and receives more thermal cycling than HSR and VHSR, and grain size is inversely related to sheet resistance). Nevertheless, the results of chlorine implant described herein may prove beneficial and consistent across these variables. Accordingly, one or more of these benefits may be realized for more complex structures, or for multiple devices on the same substrate (and IC), thereby realizing scaled improvement across the device. Still additional modifications are possible in the described examples, and other examples are possible, within the scope of the following claims.

What is claimed is:

1. A method of forming an integrated circuit, comprising:
forming plural semiconductor bodies, over a semiconductor substrate, wherein a first semiconductor body in the plural semiconductor bodies corresponds to a resistor and a second semiconductor body in the plural semiconductor bodies corresponds to a transistor;
forming a mask over the semiconductor substrate, the mask including a first open area providing an unmasked portion of the first semiconductor body and a second open area providing an unmasked portion in or adjacent the second semiconductor body; and
implanting at least one of an n-type dopant or a p-type dopant, and chlorine, through the first open area into the first semiconductor body and through the second open area into a region in or adjacent the second semiconductor body.

2. The method of claim 1, wherein the step of implanting at least one of an n-type or p-type dopant includes implanting the n-type dopant with a dose in a range between 0.8e15 to 1e16 atoms/cm².

3. The method of claim 2 wherein the region in or adjacent to the second semiconductor body includes implanting the n-type dopant into a MOS transistor gate.

4. The method of claim 1, wherein the step of implanting at least one of an n-type or p-type dopant includes implanting the n-type dopant with a dose in a range between 0.8e15 to 5e15 atoms/cm².

5. The method of claim 4 wherein the region in or adjacent to the second semiconductor body includes implanting the n-type dopant into a cathode of a diode.

6. The method of claim 4 wherein the region in or adjacent to the second semiconductor body includes implanting the n-type dopant into one of either a base or a combination of a junction and emitter of a bipolar junction transistor.

7. The method of claim 4 wherein the region in or adjacent to the second semiconductor body includes implanting the n-type dopant into a source and drain of an NMOS transistor.

8. The method of claim 1, wherein the step of implanting at least one of an n-type or p-type dopant includes implanting the p-type dopant with a dose in a range between 0.8e15 to 4e15 atoms/cm².

9. The method of claim 8 wherein the region in or adjacent to the second semiconductor body includes implanting the p-type dopant into an anode of a diode.

10. The method of claim 8 wherein the region in or adjacent to the second semiconductor body includes implanting the p-type dopant into one of a base or a combination of a junction and emitter of a bipolar junction transistor.

11. The method of claim 4 wherein the region in or adjacent to the second semiconductor body includes implanting the p-type dopant into a source and drain of an PMOS transistor.

12. The method of claim 1, wherein the step of implanting chlorine includes implanting the chlorine with a dose in a range between 2e14 to 8e15 atoms/cm².

13. The method of claim 1 wherein the implanting implants the at least one of an n-type or p-type dopant before implanting the chlorine.

14. A method of forming an integrated circuit, comprising:
forming a semiconductor body corresponding to a resistor, over a first region of a semiconductor substrate; and
implanting at least one of an n-type or p-type dopant, and chlorine, into the semiconductor body and into a different second region in the semiconductor substrate.

15. The method of claim 14, wherein the second region includes a device selected from the group consisting of a diode and a transistor.

16. The method of claim 15 wherein the transistor is a bipolar junction transistor.

17. The method of claim 15 wherein the transistor is a MOS transistor.

18. An integrated circuit, comprising:
plural semiconductor bodies, over a semiconductor substrate, wherein a first semiconductor body in the plural semiconductor bodies corresponds to a resistor and a second semiconductor body in the plural semiconductor bodies corresponds to a transistor; and
at least one of a n-type or p-type dopant, along with chlorine, in the first semiconductor body and in a region either in or adjacent the second semiconductor body.

19. The integrated circuit of claim 18, wherein the at least one of an n-type or p-type dopant, along with chlorine, is in a transistor gate.

20. The integrated circuit of claim 18, wherein the at least one of an n-type or p-type dopant, along with chlorine, is in a transistor source/drain.
